(19) United States
(12) Patent Application Publication
(10) Pub. No.: US 2025/0364294 A1
(43) Pub. Date: Nov. 27, 2025

(54) PROCESSING APPARATUS AND PROCESSING METHOD

(71) Applicant: DISCO CORPORATION, Tokyo (JP)

(72) Inventor: Kazuma Sekiya, Tokyo (JP)

(21) Appl. No.: 19/184,139

(22) Filed: Apr. 21, 2025

(30) Foreign Application Priority Data
May 21, 2024 (JP) 2024-082624

(51) Int. Cl. H01L 21/677; H01L 21/67; H01L 21/68

(52) U.S. Cl. CPC H01L 21/67778; H01L 21/67259; H01L 21/681

(57) ABSTRACT

A processing apparatus is for processing a semiconductor wafer. The semiconductor wafer includes a front surface, a back surface of a rear surface of the front surface, a side surface extending from the front surface to the back surface, and has a flat mirror surface portion indicating a crystal orientation of the semiconductor wafer on the side surface. The processing apparatus includes: a placement table on which a wafer cassette configured to store the semiconductor wafer is placed, a detection unit that detects the flat mirror surface portion; and a transport unit that transports the semiconductor wafer whose flat mirror surface portion is detected by the detection unit to the wafer cassette placed on the placement table. The transport unit stores the semiconductor wafer into the wafer cassette such that the flat mirror surface portion is in a predetermined orientation with respect to the wafer cassette.

### CROSS-REFERENCE TO RELATED APPLICATION(S)

The present application claims priority to and incorporates by reference the entire contents of Japanese Patent Application No. 2024-082624 filed in Japan on May 21, 2024.

### TECHNICAL FIELD

The present disclosure relates to a processing apparatus and a processing method for processing a semiconductor wafer.

### BACKGROUND

In a wafer made of a semiconductor material, a cutout such as a notch or an orientation flat is formed on the outer periphery of the wafer as a mark indicating the crystal orientation of the wafer.

In a process of manufacturing a semiconductor device, a notch or an orientation flat is mainly used for rough alignment of the wafer. In various apparatuses in the process of manufacturing the semiconductor device, the cutout at the wafer outer peripheral edge is detected, and the wafer is positioned in a predetermined orientation based on the position of the cutout.

Thus, a method for detecting a notch or the like has been conventionally used (see, for example, JP 2022-072520 A).

However, in a wafer having a notch or an orientation flat, the number of devices that can be formed on the front surface is limited, and thus improvement has been strongly desired.

By not forming the cutout in the wafer, the number of devices that can be formed on the front surface can be increased as compared with a wafer in which the cutout is formed. However, in the device in the related art in which the wafer is positioned in the predetermined orientation based on the position of the cutout, there arises a problem that the wafer having no cutout cannot be positioned in the predetermined orientation, that is, the wafer cannot be positioned so that the crystal orientation is in a predetermined orientation.

### SUMMARY

A processing apparatus according to an aspect of the present disclosure is for processing a semiconductor wafer. The semiconductor wafer includes a front surface, a back surface of a rear surface of the front surface, and a side surface extending from the front surface to the back surface, and has a flat mirror surface portion indicating a crystal orientation of the semiconductor wafer on the side surface. The processing apparatus includes: a placement table on which a wafer cassette configured to store the semiconductor wafer is placed, a detection unit that detects the flat mirror surface portion; and a transport unit that transports the semiconductor wafer whose flat mirror surface portion is detected by the detection unit to the wafer cassette placed on the placement table. The transport unit stores the semiconductor wafer into the wafer cassette such that the flat mirror surface portion is in a predetermined orientation with respect to the wafer cassette.

A processing method according to another aspect of the present disclosure is for processing a semiconductor wafer. The semiconductor wafer includes a front surface, a back surface of a rear surface of the front surface, and a side surface extending from the front surface to the back surface, and has a flat mirror surface portion indicating a crystal orientation of the semiconductor wafer on the side surface. The processing method includes: detecting the flat mirror surface portion of the semiconductor wafer; and storing the semiconductor wafer in a wafer cassette such that the flat mirror surface portion is in a predetermined orientation.

### BRIEF DESCRIPTION OF THE DRAWINGS

FIG. 1 is a perspective view schematically illustrating a semiconductor wafer to be processed by a processing method according to a first embodiment;

FIG. 2 is a perspective view schematically illustrating the semiconductor wafer illustrated in FIG. 1 from a back surface side;

FIG. 3 is a flowchart illustrating a flow of the processing method according to the first embodiment;

FIG. 4 is a perspective view schematically illustrating a configuration example of a processing apparatus that performs a detection step and a storing step of the processing method illustrated in FIG. 3;

FIG. 5 is a plan view illustrating an example of a semiconductor wafer stored in a wafer cassette installed on a first cassette placement table in the detection step of the processing method illustrated in FIG. 3 in a partial cross section;

FIG. 6 is a side view schematically illustrating the detection step of the processing method illustrated in FIG. 3;

FIG. 7 is another side view schematically illustrating the detection step of the processing method illustrated in FIG. 3;

FIG. 8 is a front view schematically illustrating the wafer cassette storing wafers in the storing step of the processing method illustrated in FIG. 3;

FIG. 9 is a cross-sectional view taken along line IX-IX in FIG. 8;

FIG. 10 is a perspective view schematically illustrating a configuration of a tape mounter that performs a transport step of the processing method illustrated in FIG. 3;

FIG. 11 is a plan view schematically illustrating a work unit formed by the tape mounter illustrated in FIG. 10; and

FIG. 12 is a perspective view schematically illustrating a state in which the semiconductor wafer and the frame are mounted on a tape bonding stage in the transport step of the processing method illustrated in FIG. 3.

### DETAILED DESCRIPTION

An embodiment of the present disclosure is described in detail with reference to the drawings. The present invention is not limited by the contents described in the following embodiment. In addition, the components described below include those that can be easily assumed by those skilled in the art and those that are substantially the same. Furthermore, the configurations described below can be appropriately combined. In addition, various omissions, substitutions, or changes in the configuration can be made without departing from the gist of the present invention.

### First Embodiment

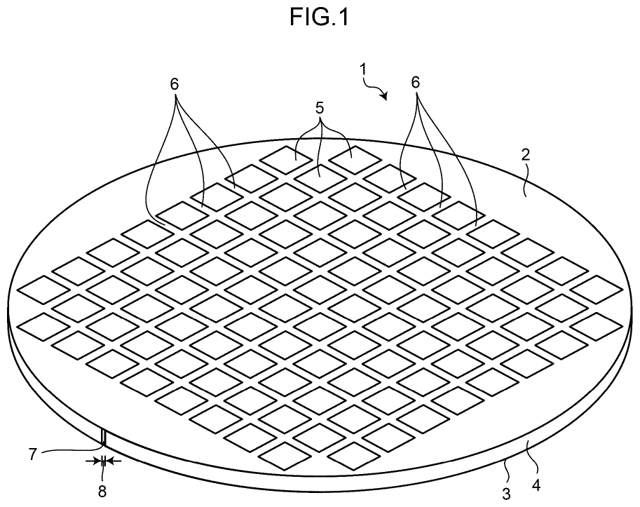

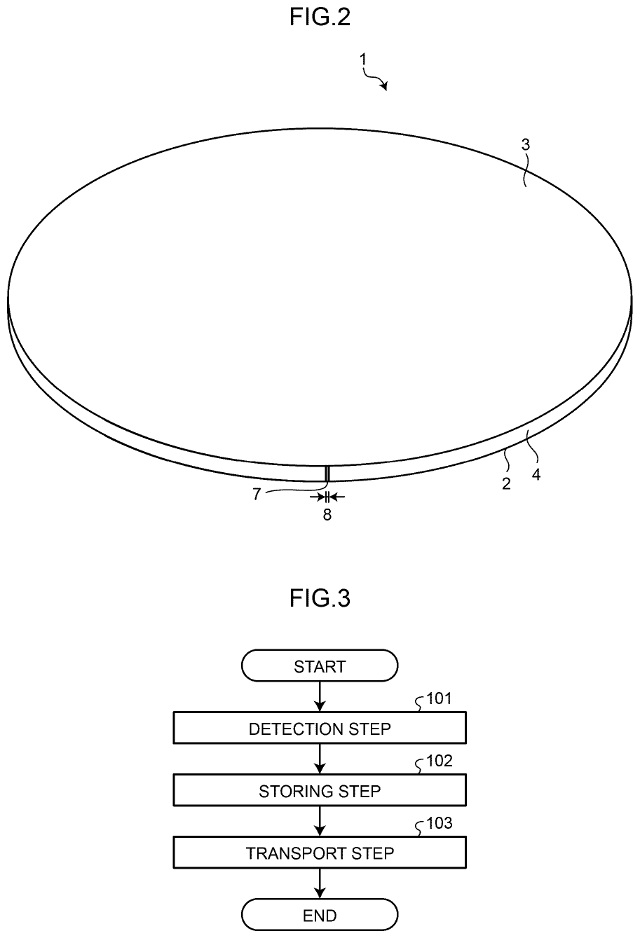

A processing method according to a first embodiment of the present disclosure is described with reference to the drawings. FIG. 1 is a perspective view schematically illustrating a semiconductor wafer to be processed by a processing method according to the first embodiment. FIG. 2 is a perspective view schematically illustrating the semiconductor wafer illustrated in FIG. 1 from a back surface side. FIG. 3 is a flowchart illustrating a flow of the processing method according to the first embodiment.

### Semiconductor Wafer

The processing method according to the first embodiment is a method of processing a semiconductor wafer 1 illustrated in FIGS. 1 and 2. The semiconductor wafer 1 to be processed by the processing method according to the first embodiment is made of silicon and is formed in a disk shape as a whole as illustrated in FIGS. 1 and 2 in the first embodiment. In the first embodiment, the semiconductor wafer 1 is made of single crystal silicon which is a semiconductor material. Note that, in the present invention, the semiconductor material configuring the semiconductor wafer 1 is not limited to silicon.

As illustrated in FIGS. 1 and 2, the semiconductor wafer 1 includes a circular front surface 2, a circular back surface 3 that is a rear surface of the front surface 2, and a side surface 4 extending from an outer edge of the front surface 2 to an outer edge of the back surface 3. The front surface 2 and the back surface 3 are formed flat, have the same diameter, and are arranged in parallel to each other. In the first embodiment, the side surface 4 of the semiconductor wafer 1 is formed in a linear shape in a vertical cross section that is a cross section passing through the axial center of the semiconductor wafer 1.

In the first embodiment, devices 5 are formed on the front surface 2 of the semiconductor wafer 1. The devices 5 are formed in a region defined by a plurality of planned division lines 6 intersecting each other on the front surface 2. Examples of the devices 5 include an integrated circuit (IC), a large scale integration (LSI), an image sensor such as a charge coupled device (CCD) or a complementary metal oxide semiconductor (CMOS), and a memory (semiconductor storage device). In the present invention, the semiconductor wafer 1 may have no device formed on the front surface 2.

In the first embodiment, the semiconductor wafer 1 has a flat mirror surface portion 7 indicating a crystal orientation as illustrated in FIGS. 1 and 2. In the first embodiment, the flat mirror surface portion 7 is formed to be recessed from the side surface 4, extends along the thickness direction of the semiconductor wafer 1, and is formed over the entire length in the thickness direction. However, in the present invention, the flat mirror surface portion 7 may be formed on at least a part of the semiconductor wafer 1 in a thickness direction. In addition, in the example illustrated in FIGS. 1 and 2, in the semiconductor wafer 1, the flat mirror surface portion 7 is formed on a (011) plane.

The bottom of the flat mirror surface portion 7 is formed to be a mirror surface. For this reason, the flat mirror surface portion 7 of the semiconductor wafer 1 has a higher light reflectance than the side surface 4. A width 8 of the flat mirror surface portion 7 is 0.05 mm or more and 34.5 mm or less. The reason for setting the width 8 of the flat mirror surface portion 7 to be 0.05 mm or more and 34.5 mm or less is that, when the width 8 is less than 0.05 mm, the flat mirror surface portion 7 cannot be detected in a detection step 101 described below, and when the width 8 exceeds 34.5 mm, the number of devices 5 formed on the semiconductor wafer 1 decreases, which is undesirable.

In the present invention, the width 8 of the flat mirror surface portion 7 is preferably 0.05 mm or more and 10 mm or less and is preferably 0.05 mm or more and 5 mm or less. In short, it is desirable that the width 8 of the flat mirror surface portion 7 is as narrow as possible as long as it is 0.05 mm or more, because the number of devices 5 formed on the semiconductor wafer 1 does not decrease. In the first embodiment, the width 8 of the flat mirror surface portion 7 is 1 mm.

### Processing Method

The processing method according to the first embodiment is a processing method for processing the semiconductor wafer 1 having the above-described configuration, and includes the detection step 101, a storing step 102, and a transport step 103 as illustrated in FIG. 3.

### Processing Apparatus

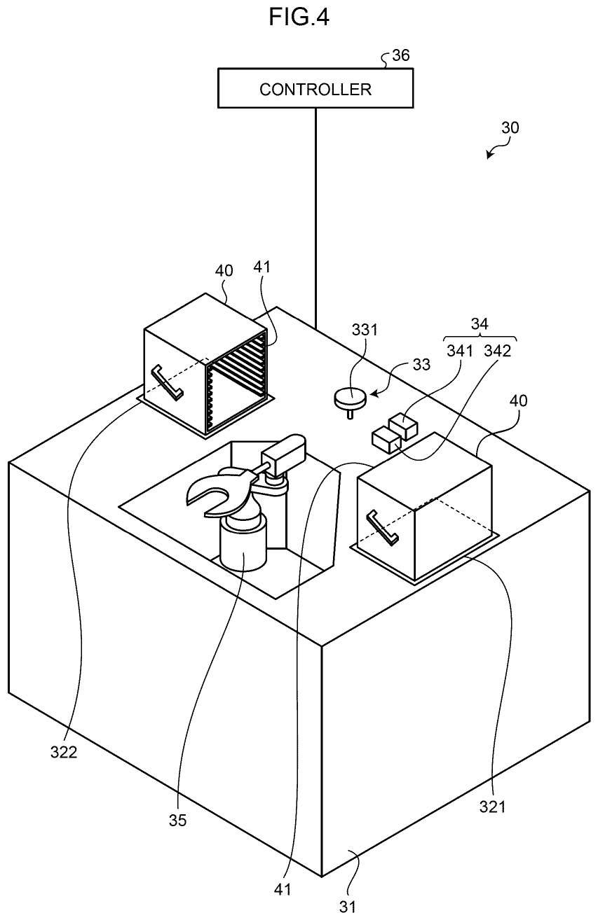

The detection step 101 and the storing step 102 are performed by a processing apparatus 30 illustrated in FIG. 4. Next, the processing apparatus 30 is described. FIG. 4 is a perspective view schematically illustrating a configuration example of the processing apparatus that performs the detection step and the storing step of the processing method illustrated in FIG. 3.

The processing apparatus 30 detects the flat mirror surface portion 7 of the semiconductor wafer 1 to detect the crystal orientation. As illustrated in FIG. 4, the processing apparatus 30 includes an apparatus base 31, a first cassette placement table 321 (corresponding to a placement table) mounted on the apparatus base 31, a second cassette placement table 322 (corresponding to a placement table) mounted on the apparatus base 31, a holding unit 33 mounted on the apparatus base 31, a detection unit 34, a transport unit 35, and a controller 36.

Wafer cassettes 40 are place on the cassette placement tables 321 and 322, respectively. Each of the wafer cassettes 40 is a storage container having a plurality of slots and stores a plurality of semiconductor wafers 1 at intervals in a vertical direction. The wafer cassettes 40 store a plurality of semiconductor wafers 1 before and after the crystal orientations are detected.

In the first embodiment, the cassette placement tables 321 and 322 support the wafer cassettes 40 to be movable up and down in the Z-axis direction. In the first embodiment, the wafer cassettes 40 are placed on the cassette placement tables 321 and 322 such that openings 41 of the wafer cassettes 40 through which the semiconductor wafers 1 are taken in and out face each other. The wafer cassette 40 storing the semiconductor wafer 1 before the crystal orientation is detected is mounted on the first cassette placement table 321. The wafer cassette 40 storing the semiconductor wafer 1 after the crystal orientation is detected is mounted on the second cassette placement table 322.

The holding unit 33 and the detection unit 34 are provided between the cassette placement tables 321 and 322 of the apparatus base 31. The holding unit 33 holds the semiconductor wafer 1 on an upper surface 331 formed to be flat along a horizontal direction. The holding unit 33 rotates about an axis parallel to the vertical direction and is formed in a disk shape having a diameter smaller than that of the semiconductor wafer 1. The holding unit 33 holds the semiconductor wafer 1 on the upper surface 331 by suction.

The detection unit 34 detects the flat mirror surface portion 7 of the semiconductor wafer 1 held by the holding unit 33 to detect the crystal orientation of the semiconductor wafer. In the detection unit 34, the detection unit 34 faces the side surface 4 of the semiconductor wafer 1 held by the holding unit 33 in the horizontal direction. The detection unit 34 includes a light emitting unit 341 that emits light 343 toward the side surface 4 of the semiconductor wafer 1 held by the holding unit 33 and a light receiving unit 342 that receives reflected light 344 from the side surface 4. The detection unit 34 detects the light amount of the reflected light 344 received by the light receiving unit 342 and outputs the detected light amount to the controller 36. The detection unit 34 detects the flat mirror surface portion 7 by the light receiving unit 342 outputting the light amount of the reflected light 344 to the controller 36.

The transport unit 35 transports the semiconductor wafer 1 between the wafer cassette 40 mounted on the cassette placement tables 321 and 322 and the holding unit 33. The transport unit 35 transports the semiconductor wafer 1 before the flat mirror surface portion 7 is detected from the wafer cassette 40 placed on the first cassette placement table 321 to the holding unit 33 and transports the semiconductor wafer 1 of which the flat mirror surface portion 7 is detected by the detection unit 34 from the holding unit 33 to the wafer cassette 40 placed on the second cassette placement table 322. In the first embodiment, the transport unit 35 is, for example, a robot pick including a U-shaped hand and holds the semiconductor wafer 1 by suction with the U-shaped hand to transport the semiconductor wafer 1.

The controller 36 controls each component of the processing apparatus 30 to cause the processing apparatus 30 to perform an operation of detecting the crystal orientation for the semiconductor wafer 1. Note that the controller 36 is a computer including an arithmetic processing device with a microprocessor such as a central processing unit (CPU), a storage device with a memory such as a read only memory (ROM) or a random access memory (RAM), and an input/output interface device. The arithmetic processing device of the controller 36 performs arithmetic processing according to a computer program stored in the storage device and outputs a control signal for controlling the processing apparatus 30 to each component of the processing apparatus 30 via the input/output interface device.

The controller 36 is connected to a display unit (not illustrated) configured with a liquid crystal display device or the like that displays a state of a processing operation, an image, or the like, and an input unit (not illustrated) used when an operator registers processing content information or the like. The input unit is configured with at least one of a touch panel provided on the display unit and an external input device such as a keyboard.

### Detection Step

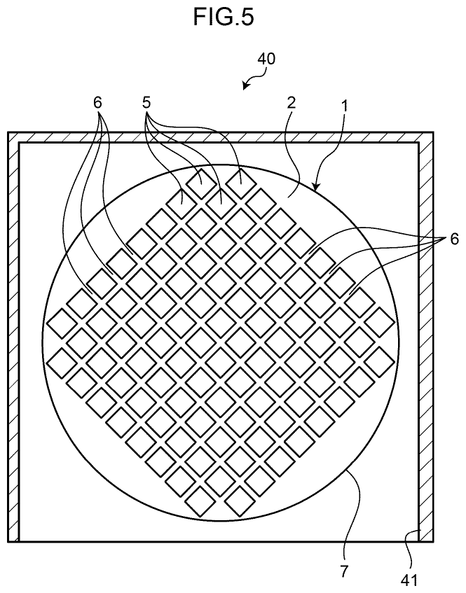

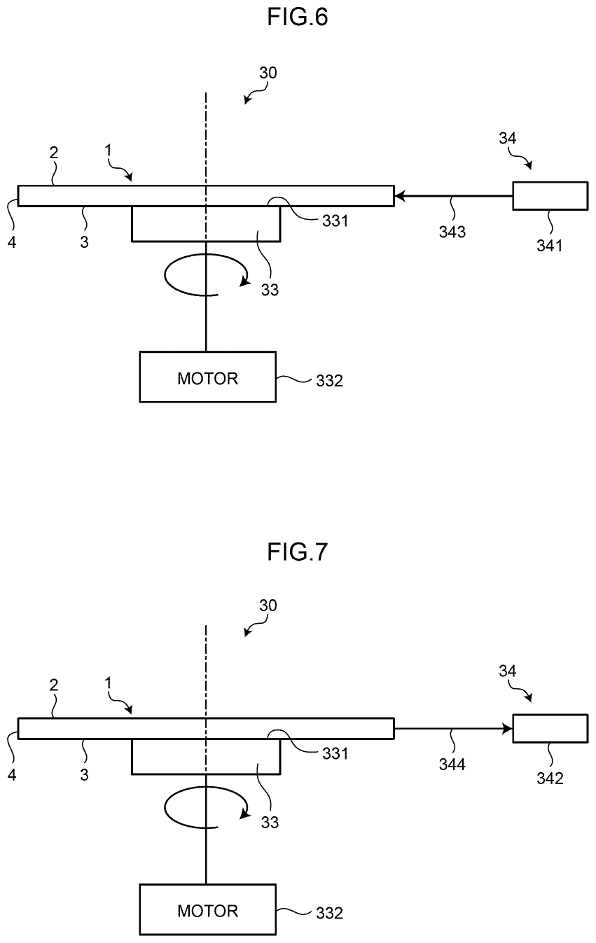

Next, the detection step 101 is described. FIG. 5 is a plan view illustrating an example of the semiconductor wafer stored in the wafer cassette mounted on the first cassette placement table in the detection step of the processing method illustrated in FIG. 3 in a partial cross section. FIG. 6 is a side view schematically illustrating the detection step of the processing method illustrated in FIG. 3. FIG. 7 is another side view schematically illustrating the detection step of the processing method illustrated in FIG. 3. The detection step 101 is a step of detecting the flat mirror surface portion 7 of the semiconductor wafer 1.

In the first embodiment, in the detection step 101, the semiconductor wafer 1 is stored in the wafer cassette 40. At this time, the back surface 3 of the semiconductor wafer 1 is positioned downward, and the front surface 2 is exposed upward. In a state where the semiconductor wafer 1 is stored in the wafer cassette 40, the flat mirror surface portion 7 is randomly positioned at any position (that is, a random position) as illustrated in an example in FIG. 5. In the present invention, the front surface 2 of the semiconductor wafer 1 may be positioned downward, and the back surface 3 may be exposed upward to store the semiconductor wafer 1 in the wafer cassette 40. In the first embodiment, in the detection step 101, the wafer cassette 40 storing the semiconductor wafer 1 is placed on the first cassette placement table 321, and the wafer cassette 40 not storing the semiconductor wafer 1 is placed on the second cassette placement table 322. In the first embodiment, in the detection step 101, the processing conditions are registered in the controller 36 by the operator, and when the controller 36 receives an instruction to start the processing operation from the operator, the processing apparatus 30 starts the detection operation of the crystal orientation. Note that the processing conditions include the orientation of the flat mirror surface portion 7 of the semiconductor wafer 1 stored in the wafer cassette 40 placed on the second cassette placement table 322.

In the first embodiment, in the detection step 101, the processing apparatus 30 causes the controller 36 to cause the transport unit 35 to take out one semiconductor wafer 1 from the wafer cassette 40 placed on the first cassette placement table 321 and place the semiconductor wafer 1 on the upper surface 331 of the holding unit 33.

In the first embodiment, in the detection step 101, the processing apparatus 30 causes the controller 36 to hold the front surface 2 of the semiconductor wafer 1 on the upper surface 331 of the holding unit 33 by suction, causes the light 34 to be emitted from the light emitting unit 341 while rotating the holding unit 33 about the axis by the motor 332 as illustrated in FIGS. 6 and 7, and causes the light receiving unit 342 to receive the reflected light 344. In the first embodiment, in the detection step 101, the controller 36 of the processing apparatus 30 stops the rotation about the axis of the holding unit 33 at an angle at which the light amount of the reflected light 344 is maximized based on the detection result of the light receiving unit 342.

### Storing Step

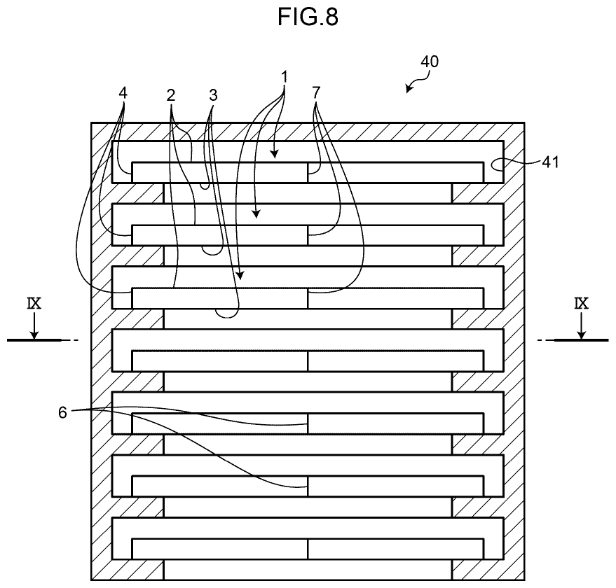

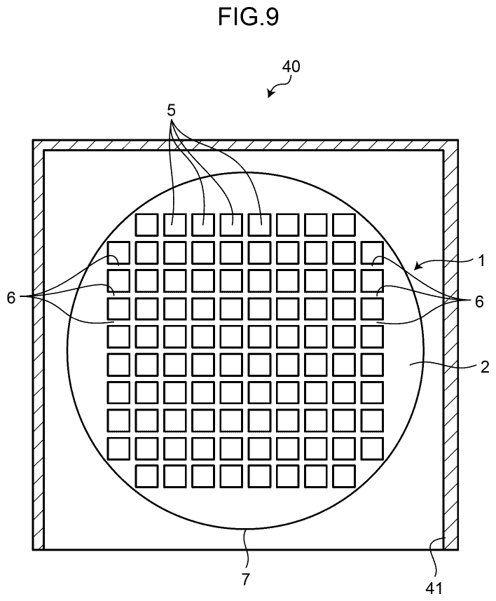

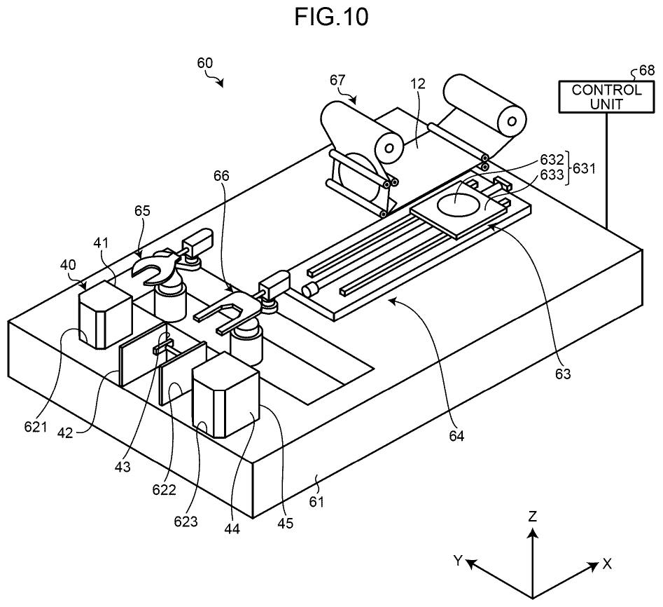

FIG. 8 is a front view schematically illustrating the wafer cassette storing wafers in the storing step of the processing method illustrated in FIG. 3. FIG. 9 is a cross-sectional view taken along line IX-IX in FIG. 8. The storing step 102 is a step of storing the semiconductor wafer 1 in the wafer cassette 40 such that the flat mirror surface portion 7 is in a predetermined orientation after the detection step 101 is performed.

In the first embodiment, in the storing step 102, the processing apparatus 30 stops holding of the semiconductor wafer 1 on the upper surface 331 of the holding unit 33 by suction and causes the transport unit 35 to transport the semiconductor wafer 1 from the upper surface 331 of the holding unit 33 into the wafer cassette 40 placed on the second cassette placement table 322. At this time, in the first embodiment, in the storing step 102, the processing apparatus 30 stores the semiconductor wafer 1 in the wafer cassette 40 by the transport unit 35 such that the flat mirror surface portion 7 is positioned at the center in the width direction of the semiconductor wafer 1 when viewed from the front of the opening 41 for taking in and out the semiconductor wafer 1 of the wafer cassette 40, for example, as illustrated in FIGS. 8 and 9.

Thus, in the first embodiment, in the storing step 102, in the processing apparatus 30, the flat mirror surface portions 7 of the semiconductor wafers 1 stored in the wafer cassette 40 placed on the second cassette placement table 322 are aligned in the thickness direction of the semiconductor wafer 1. In this manner, in the storing step 102, the transport unit 35 stores the semiconductor wafer 1 into the wafer cassette 40 such that the flat mirror surface portion 7 is in a predetermined orientation with respect to the wafer cassette 40, whereby the semiconductor wafer 1 can be stored in the wafer cassette 40 placed on the second cassette placement table 322 such that the flat mirror surface portion 7 of the semiconductor wafer 1 transported to the transport destination in the transport step 103 is positioned in the predetermined orientation. In the present invention, the predetermined orientation in which the semiconductor wafer 1 is stored in the wafer cassette 40 is not limited to the orientations illustrated in FIGS. 8 and 9.

### Tape Mounter

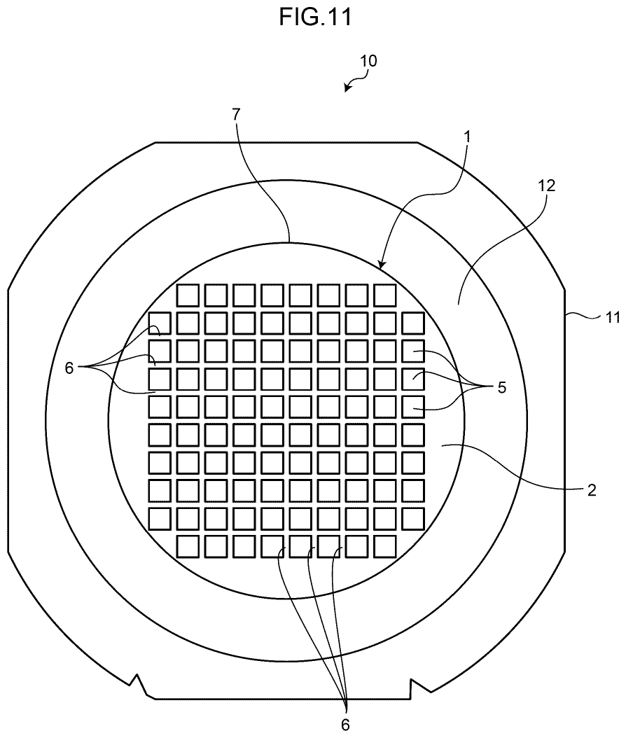

The transport step 103 is performed by a tape mounter 60 illustrated in FIG. 10, that is a device for performing the next process of the processing apparatus 30. Next, the tape mounter 60 is described. FIG. 10 is a perspective view schematically illustrating a configuration of the tape mounter that performs the transport step of the processing method illustrated in FIG. 3. FIG. 11 is a plan view schematically illustrating a work unit formed by the tape mounter illustrated in FIG. 10.

The tape mounter 60 illustrated in FIG. 10 is a device in which a disk-shaped tape 12 having a larger diameter than the semiconductor wafer 1 is bonded to the back surface 3 of the semiconductor wafer 1, and an annular frame 11 is attached to the outer edge portion of the tape 12 to form a work unit 10 illustrated in FIG. 11. As illustrated in FIG. 10, the tape mounter 60 includes an apparatus base 61, a cassette placement table 621, a frame cassette placement table 622, a work cassette placement table 623, a tape bonding stage 63, a stage moving unit 64, a wafer transport unit 65, a frame transport unit 66, a bonding unit 67, and a control unit 68.

The cassette placement tables 621, 622, and 623 are arranged in the Y-axis direction that is parallel to the horizontal direction and orthogonal to the X-axis direction in one end portion in the X-axis direction that is a longitudinal direction parallel to the horizontal direction of the apparatus base 61. The wafer cassette 40 storing the semiconductor wafer 1 with the flat mirror surface portion 7 positioned in a predetermined orientation by the processing apparatus 30 in the storing step 102 is placed on the cassette placement table 621.

A frame cassette 42 storing the plurality of frames 11 is placed on the frame cassette placement table 622. The frame cassette 42 is a storage container having a plurality of slots and capable of storing the plurality of frames 11 at intervals in a vertical direction.

A work unit cassette 44 capable of storing the plurality of work units 10 is placed on the work cassette placement table 623. The work unit cassette 44 is a storage container having a plurality of slots and capable of storing the plurality of work units 10 at intervals in a vertical direction.

In the first embodiment, the cassette placement tables 621, 622, and 623 respectively support the cassettes 40, 42, and 44 to be movable up and down in the Z-axis direction parallel to the vertical direction. In the first embodiment, the cassette 40 is placed on the cassette placement table 621 such that the opening 41 through which the semiconductor wafers 1 of the wafer cassette 40 is taken in and out face the other end side in the X-axis direction. The cassette 42 is placed on the cassette placement table 622 such that an opening 43 through which the frames 11 of the frame cassette 42 are taken in and out face the other end side in the X-axis direction. The cassette 44 is placed on the cassette placement table 623 such that an opening 45 through which the work units 10 of the work unit cassette 44 are taken in and out face the other end side in the X-axis direction.

The semiconductor wafer 1 and the frame 11 are placed on an upper surface 631 of the tape bonding stage 63. The upper surface 631 of the tape bonding stage 63 includes an annular frame holding portion 633 that holds the frame 11 and a wafer holding portion 632 that holds the semiconductor wafer 1. An opening is formed at the center of the frame holding portion 633, and the wafer holding portion 632 is disposed in the opening of the frame holding portion 633.

The stage moving unit 64 is mounted on the apparatus base 61, and moves the tape bonding stage 63 in the X-axis direction throughout a carry-in/out position where the semiconductor wafer 1 and the frame 11 are carried in and the work unit 10 is carried out and a bonding position that is a transport destination where the tape 12 is bonded to the semiconductor wafer 1 and the frame 11 held by the tape bonding stage 63. The stage moving unit 64 includes a known ball screw provided rotatably about the axis, a known motor that rotates the ball screw about the axis, and a known guide rail that supports the tape bonding stage 63 to be movable in the X-axis direction.

The wafer transport unit 65 transports the semiconductor wafer 1 from the wafer cassette 40 placed on the cassette placement table 621 to the wafer holding portion 632 of the tape bonding stage 63 positioned at the carry-in/out position. The frame transport unit 66 transports the frame 11 from the frame cassette 42 placed on the frame cassette placement table 622 to the frame holding portion 633 of the tape bonding stage 63 positioned at the carry-in/out position and stores the work unit 10 into the work unit cassette 44 placed on the work cassette placement table 623 from the upper surface 631 of the tape bonding stage 63 positioned at the carry-in/out position. In the first embodiment, the transport units 65 and 66 each are, for example, a robot pick including a U-shaped hand and hold the semiconductor wafer 1, the frame 11, and the work unit 10 with the U-shaped hand by suction to transport the semiconductor wafer 1, the frame 11, and the work unit 10.

The bonding unit 67 bonds the tape 12 to the semiconductor wafer 1 and the frame 11 held by the tape bonding stage 63 positioned at the bonding position and cuts the tape 12 between the inner edge and the outer edge of the frame 11 to form the work unit 10.

The control unit 68 controls each of the above-described configuration units configuring the tape mounter 60 to cause the tape mounter 60 to execute an operation of forming the work unit 10. The control unit 68 is a computer including an arithmetic processing device with a microprocessor such as a central processing unit (CPU), a storage device with a memory such as a read only memory (ROM) or a random access memory (RAM), and an input/output interface device.

The arithmetic processing device of the control unit 68 performs arithmetic processing according to a computer program stored in the storage device and outputs a control signal for controlling the tape mounter 60 to the above-described component of the tape mounter 60 via the input/output interface device. In addition, the control unit 68 is connected to a display unit configured with a liquid crystal display device or the like that displays a state of a processing operation, an image, or the like, an input unit used when an operator registers information or the like, and a notification unit that notifies the operator of the information or the like.

The input unit is configured with at least one of a touch panel provided on the display unit and a keyboard. The notification unit emits at least one of sound, light, and a message on the touch panel to notify the operator.

### Transport Step

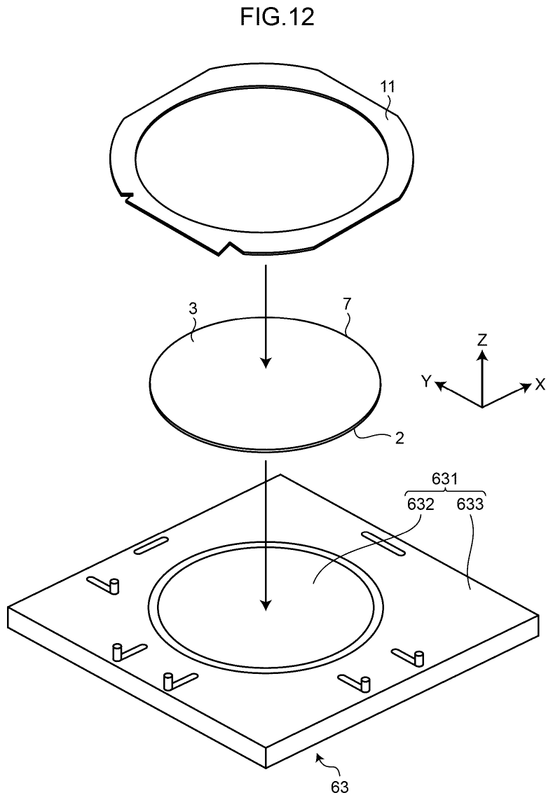

Next, the transport step 103 is described. FIG. 12 is a perspective view schematically illustrating a state in which the semiconductor wafer and the frame are placed on the tape bonding stage in the transport step of the processing method illustrated in FIG. 3. The transport step 103 is a step of transporting the semiconductor wafer 1 from the wafer cassette 40 to the bonding position that is the transport destination with the stage moving unit 64 that is a predetermined transport path after performing the storing step 102.

In the first embodiment, in the transport step 103, the wafer cassette 40 storing the semiconductor wafer 1 with the flat mirror surface portion 7 positioned in the predetermined orientation in the storing step 102 is placed on the cassette placement table 621, the frame cassette 42 storing the plurality of frames 11 is placed on the frame cassette placement table 622, and the work unit cassette 44 not storing the work unit 10 is placed on the work cassette placement table 623. In the first embodiment, in the transport step 103, when a bonding condition is registered in the control unit 68 by the operator, and the control unit 68 receives an instruction to start the bonding operation from the operator, the tape mounter 60 starts the bonding operation.

In the first embodiment, in the transport step 103, as illustrated in FIG. 12, the tape mounter 60 places the semiconductor wafer 1 storing the wafer cassette 40 on the tape bonding stage 63 in a state of positioning the flat mirror surface portion 7 at the predetermined position. Specifically, in the first embodiment, in the transport step 103, the tape mounter 60 causes the wafer transport unit 65 to take out the semiconductor wafer 1 from the wafer cassette 40 placed on the cassette placement table 621 with a constant operation and places the front surface 2 side of the semiconductor wafer 1 on the wafer holding portion 632 of the tape bonding stage 63.

As such, in the transport step 103, since the semiconductor wafer 1 is stored in the wafer cassette 40 in the predetermined orientation, the semiconductor wafer 1 is positioned such that the flat mirror surface portion 7 is at a predetermined position when the semiconductor wafer 1 is transported onto the tape bonding stage 63. That is, in the storing step 102, the semiconductor wafer 1 is stored in the wafer cassette 40 in advance with the flat mirror surface portion 7 in the predetermined orientation with respect to the wafer cassette 40 so that the flat mirror surface portion 7 of the semiconductor wafer 1 transported to the transport destination in the transport step 103 in the next process of the processing apparatus 30 is at the predetermined position. In the first embodiment, in the transport step 103, as illustrated in FIG. 12, the tape mounter 60 causes the frame transport unit 66 to take out the frame 11 from the frame cassette 42 placed on the frame cassette placement table 622 with a constant operation and places the frame 11 on the frame holding portion 633 of the tape bonding stage 63.

In the first embodiment, in the transport step 103, the tape mounter 60 forms the work unit 10 by causing the stage moving unit 64 to move the tape bonding stage 63 to the bonding position and causing the bonding unit to bond the tape 12 to the back surface 3 of the semiconductor wafer 1 and the frame 11 at the bonding position. In the first embodiment, in the transport step 103, after the work unit 10 is formed, the tape mounter 60 causes the stage moving unit 64 to move the tape bonding stage 63 to the carry-in/out position and causes the frame transport unit 66 to store the work unit 10 from the tape bonding stage 63 at the carry-in/out position into the work unit cassette 44.

In the first embodiment, the tape mounter 60 transports the semiconductor wafer 1 to the transport destination in the transport step 103. However, the present invention is not limited to the tape mounter 60, and various devices that are used in a semiconductor manufacturing process such as a cutting device and an exposure device may transport the semiconductor wafer 1 to the transport destination.

In the processing method according to the first embodiment described above, the flat mirror surface portion 7 indicating the crystal orientation is formed in the semiconductor wafer 1 instead of a cutout portion such as the notch or an orientation flat, a larger number of devices 5 can be formed in the semiconductor wafer 1.

In the processing method according to the first embodiment, the flat mirror surface portion 7 indicating the crystal orientation of the semiconductor wafer 1 is detected in the detection step 101, and the semiconductor wafer 1 is stored in the wafer cassette 40 so that the flat mirror surface portion 7 is in a predetermined orientation with respect to the wafer cassette 40 in the storing step 102. Therefore, the semiconductor wafer 1 can be positioned in a predetermined orientation.

As a result, the processing method according to the first embodiment exhibits an effect that the semiconductor wafer 1 can be positioned in a predetermined orientation while a larger number of devices 5 can be formed on the semiconductor wafer 1.

According to the present disclosure, the semiconductor wafer can be positioned in a predetermined orientation while a larger number of devices can be formed on the semiconductor wafer.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing apparatus for processing a semiconductor wafer,
the semiconductor wafer including a front surface, a back surface of a rear surface of the front surface, and a side surface extending from the front surface to the back surface, and having a flat mirror surface portion indicating a crystal orientation of the semiconductor wafer on the side surface,
the processing apparatus comprising:
a placement table on which a wafer cassette configured to store the semiconductor wafer is placed,
a detection unit that detects the flat mirror surface portion; and
a transport unit that transports the semiconductor wafer whose flat mirror surface portion is detected by the detection unit to the wafer cassette placed on the placement table,
wherein the transport unit stores the semiconductor wafer into the wafer cassette such that the flat mirror surface portion is in a predetermined orientation with respect to the wafer cassette.

2. A processing method for processing a semiconductor wafer,
the semiconductor wafer including a front surface, a back surface of a rear surface of the front surface, and a side surface extending from the front surface to the back surface, and having a flat mirror surface portion indicating a crystal orientation of the semiconductor wafer on the side surface,
the processing method comprising:
detecting the flat mirror surface portion of the semiconductor wafer; and
storing the semiconductor wafer in a wafer cassette such that the flat mirror surface portion is in a predetermined orientation.

3. The processing method according to claim 2, further comprising:
transporting the semiconductor wafer from the wafer cassette to a transport destination through a predetermined transport path after the storing,
wherein the storing includes storing the semiconductor wafer in the wafer cassette such that the semiconductor wafer transported to the transport destination is positioned in a predetermined orientation.
